(19) United States
(12) Patent Application Publication
(10) Pub. No.: US 2026/0130199 A1
(43) Pub. Date: May 7, 2026

(54) SEMICONDUCTOR DEVICE INCLUDING THROUGH VIA

(71) Applicant: Samsung Electronics Co., Ltd., Suwon-si (KR)

(72) Inventors: Jungryul Lee, Suwon-si (KR); Donghoon Kwon, Suwon-si (KR)

(21) Appl. No.: 19/326,853

(22) Filed: Sep. 12, 2025

(30) Foreign Application Priority Data
Nov. 5, 2024 (KR) 10-2024-0154860

(51) Int. Cl. H01L 23/522; H01L 23/528; H01L 25/18; H10B 12/00; H10D 80/30

(52) U.S. Cl. CPC H10W 20/42; H10B 12/09; H10B 12/312; H10B 12/50; H10D 80/30; H10W 20/435; H10W 90/00

(57) ABSTRACT

A semiconductor device according to example embodiments of the present disclosure may include: a first structure; and a second structure having a peripheral circuit region, and the first structure may include: memory cells; and a cell routing interconnection line electrically connected to the memory cells, and the second structure may include: a semiconductor body; a rear insulating layer disposed on a lower surface of the semiconductor body; a first peripheral transistor; a first through-insulating pattern penetrating through the semiconductor body; and a through-via penetrating through the first through-insulating pattern and electrically connected to the cell routing interconnection line, and the first through-insulating pattern may include a first insulating pattern including a first portion adjacent to the rear insulating layer and a second portion disposed on the first portion, and a second insulating pattern disposed between a side surface of the second portion and the semiconductor body.

### CROSS-REFERENCE TO RELATED APPLICATION(S)

This U.S. non-provisional application claims benefit of priority to Korean Patent Application No. 10-2024-0154860 filed on Nov. 5, 2024 in the Korean Intellectual Property Office, the disclosure of which is incorporated herein by reference in its entirety.

### BACKGROUND

The present disclosure relates to a semiconductor device including a through-via.

Research is being conducted so as to reduce the size of elements included in semiconductor devices and improve performance thereof. For example, in DRAM, research is being conducted so as to reliably and stably form reduced-size elements, but with a decrease in the size of the elements, the performance of semiconductor devices has been deteriorated.

### SUMMARY

An aspect of the present disclosure is to provide a device having improved reliability.

However, the object of the present invention is not limited to the above-described objects, and may be variously extended without departing from the spirit and domain of the present disclosure.

A semiconductor device according to example embodiments of the present disclosure may include a first structure having a memory region; and a second structure vertically overlapping the first structure and having a peripheral circuit region, and the first structure may include: a plurality of memory cells disposed within the memory region, each memory cell of the plurality of memory cells including a vertical channel transistor and an information storage structure; and a cell routing interconnection line electrically connected to the plurality of memory cells, and the second structure may include: a semiconductor body; a rear insulating layer below the semiconductor body; a device isolating pattern defining a peripheral active region of the semiconductor body and having a lower surface at a higher vertical level than a vertical level of a lower surface of the semiconductor body, the device isolating patterns comprising a first device isolating pattern; a first through-insulating pattern penetrating through the semiconductor body, the first through-insulating pattern including a first insulating pattern including a first portion and a second portion over the first portion, and a second insulating pattern between the second portion of the first insulating pattern and the semiconductor body, over the first portion of the first insulating pattern; a second through-insulating pattern penetrating through the first device isolating pattern and the semiconductor body below the first device isolating pattern; a peripheral transistor including a first peripheral source/drain and a second peripheral source/drain disposed within the peripheral active region, a peripheral channel region between the first peripheral source/drain and the second peripheral source/drain, and a peripheral gate disposed on the peripheral channel region; and a through-via penetrating through the first through-insulating pattern and electrically connected to the cell routing interconnection line.

A semiconductor device according to example embodiments of the present disclosure may include: a first structure having a memory region; and a second structure vertically overlapping the first structure and having a peripheral circuit region, and the first structure may include: a plurality of memory cells disposed within the memory region; and a cell routing interconnection line electrically connected to the plurality of memory cells, and the second structure may include: a semiconductor body; a rear insulating layer disposed on a lower surface of the semiconductor body; a first peripheral transistor including a first peripheral source/drain and a second peripheral source/drain disposed within a first peripheral active region of the semiconductor body, a first peripheral channel region between the first peripheral source/drain and the second peripheral source/drain, and a first peripheral gate disposed on the first peripheral channel region; a first through-insulating pattern penetrating through the semiconductor body; a device isolating pattern having a lower surface disposed at a vertical level higher than a lower surface of the semiconductor body within the semiconductor body and spaced apart from the first through-insulating pattern in a horizontal direction; and a through-via penetrating through the first through-insulating pattern and the rear insulating layer and electrically connected to the cell routing interconnection line, and the first through-insulating pattern may include a first insulating pattern including a first portion adjacent to the rear insulating layer and a second portion disposed on the first portion, and a second insulating pattern disposed between a side surface of the second portion of the first insulating pattern and the semiconductor body.

A semiconductor device according to example embodiments may include: a first structure having a plurality of memory cells disposed in a memory region and a cell routing interconnection line electrically connected to the plurality of memory cells; and a second structure vertically overlapping the first structure and having a peripheral circuit region, and the second structure may include: a semiconductor body; a device isolating pattern defining a peripheral active region of the semiconductor body; a first through-insulating pattern penetrating through the semiconductor body; a peripheral transistor including a first peripheral source/drain and a second peripheral source/drain disposed within the peripheral active region, a peripheral channel region between the first peripheral source/drain and the second peripheral source/drain, and a peripheral gate disposed on the peripheral channel region; and a through-via penetrating through the first through-insulating pattern and electrically connected to the cell routing interconnection line, and the first through-insulating pattern includes a first insulating pattern having a first portion having a lower surface coplanar with a lower surface of the semiconductor body and a second portion disposed on the first portion, and a second insulating pattern on a side surface of the second portion of the first insulating pattern.

According to example embodiments of the present disclosure a semiconductor device includes a semiconductor structure including a transistor, the semiconductor structure may include a semiconductor body, a through-insulating pattern penetrating through the semiconductor body, and a through-via penetrating through the through-insulating pattern, and the through-insulating pattern may include a first insulating pattern including a first portion in contact with the semiconductor body and a second portion extending from the first portion and covered with a second insulating pattern. Therefore, an area of the semiconductor body that may be polished in a polishing process of the semiconductor body may be secured through the first portion of the first insulating pattern, so that deterioration in a subsequent process due to insufficient polishing area of the semiconductor body may be improved, thereby providing a semiconductor device having improved reliability. The effect of the present disclosure is not limited to the above-described effects, and may be variously extended without departing from the spirit and domain of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic perspective view of a semiconductor device according to example embodiments of the present disclosure;

FIG. 2A is a schematic perspective view of a bank of the semiconductor device of FIG. 1;

FIG. 2B is a circuit diagram according to an example embodiment of a first structure in a memory cell array region of the semiconductor device of FIG. 1;

FIG. 3A is a cross-sectional view illustrating an example embodiment taken along line I-I′ of the semiconductor device of FIG. 2A;

FIG. 3B is a cross-sectional view illustrating an example embodiment taken along line II-II′ of the semiconductor device of FIG. 2A;

FIG. 4 is an enlarged view of a portion of an example embodiment of the semiconductor device illustrated in FIG. 3A;

FIGS. 5 to 9 are enlarged views of portions of other example embodiments of the semiconductor device illustrated in FIG. 3A;

FIGS. 10A to 10J are views illustrating a method of manufacturing a semiconductor device according to an example embodiment of the present disclosure; and

FIGS. 11A to 11E are views illustrating a method of manufacturing a semiconductor device according to another example embodiment of the present disclosure.

### DETAILED DESCRIPTION

Hereinafter, with reference to the attached drawings, example embodiments of the present disclosure will be described in more detail. The same reference numerals are used for the same components in the drawings, and repetitive descriptions of the same components or shared features may be omitted.

Items described in the singular herein may be provided in plural, as can be seen, for example, in the drawings. Thus, the description of a single item that is provided in plural should be understood to be applicable to the remaining plurality of items unless context indicates otherwise.

Terms such as “same,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise.

It will be understood that when an element is referred to as being “connected or “on” another element, it can be directly connected to or on the other element or intervening elements may be present. In contrast, when an element is referred to as being “contacting” or “in contact with” another element (or using any form of the word “contact”), there are no intervening elements present at the point of contact.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two device, an electrically insulative underfill or mold layer, etc.) is not electrically connected to that component.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed herein in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

Spatially relative terms, such as “below,” “lower,” “upper,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

As used herein the terms “on”, “over”, “covering” or “overlapping” are intended to mean that an element is over or aside another element. The elements may be touching or not. For example, there may be layers between layers that are “on” one another. An element “on” or “over” or “stacked” over or “covering” or “overlapping” another element need not cover an entire top surface of an element below to be considered “on” or “over” or “stacked” over or “covering” or “overlapping”. The terms are intended to encompass one element “on” or “over” or “stacked” over or “covering” or “overlapping” all, or any part of, an element below it. As used herein, the words “surround”, “surrounding” and “surrounded” are intended to mean that an element is outside the other element. The elements may be touching or not. The surrounding element may or may not completely surround an inner element.

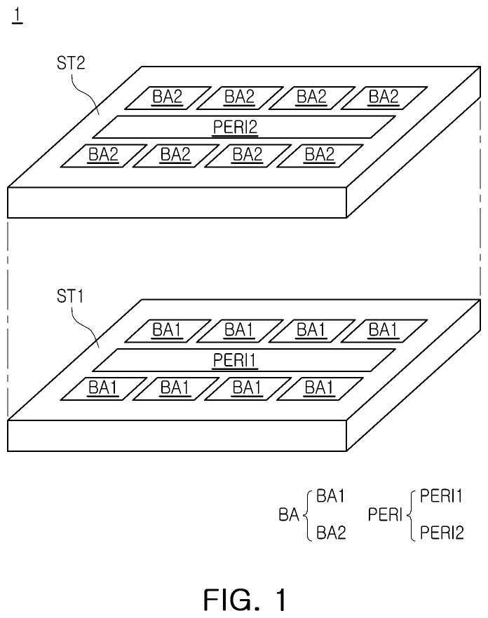

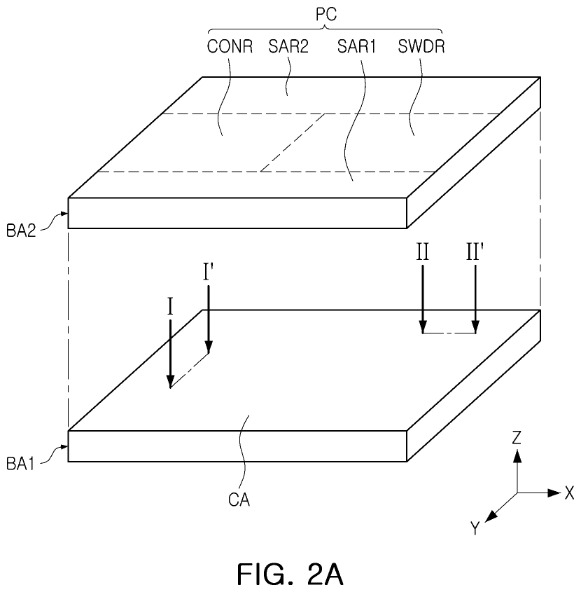

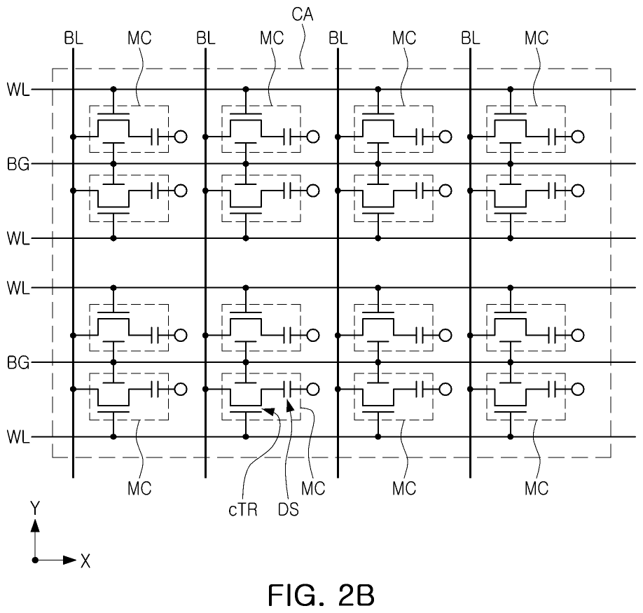

FIG. 1 is a schematic perspective view of a semiconductor device according to example embodiments of the present disclosure. FIG. 2A is a schematic perspective view of a bank of the semiconductor device of FIG. 1. FIG. 2B is a circuit diagram according to an example embodiment of a first structure in a memory cell array region of the semiconductor device of FIG. 1.

The semiconductor device may be a semiconductor chip (i.e., a semiconductor device singulated from (e.g. cut from) a wafer).

Referring to FIG. 1 and FIG. 2A, a semiconductor device 1 may include a first structure ST1 and a second structure ST2 vertically overlapping the first structure ST1. The second structure ST2 may be disposed on the first structure ST1.

The first structure ST1 may be a first chip structure including memory cells, and the second structure ST2 may be a second chip structure including peripheral circuits capable of operating the memory cells. The first structure ST1 and the second structure ST2 may be bonded and formed in a bonding process such as a wafer bonding process. Accordingly, the first structure ST1 may be in contact with and bonded to the second structure ST2.

The semiconductor device 1 may include a plurality of banks BA and a peripheral circuit region PERI. The peripheral circuit region PERI may include a first peripheral region PERI1 within the first structure ST1 and a second peripheral region PERI2 within the second structure ST2. The peripheral circuit region PERI may be a peripheral circuit region in which peripheral circuits for input/output of data or commands, or input of power/ground, are disposed.

Each of the plurality of banks BA may include a first bank region BA1 within the first structure ST1 and a second bank region BA2 within the second structure ST2.

Referring to FIGS. 2A and 2B, the first bank region BA1 within the first structure ST1 may include memory cell array regions CA. The memory cell array regions CA may include memory cells. The memory cell array regions CA may be arranged in a first direction (X-direction) and a second direction (Y-direction). Each memory cell array region CA may include memory cells MC arranged in the first direction (X-direction) and the second direction (Y-direction), word lines WL connected to the memory cells MC and extending in the first direction (X-direction), and bit lines BL connected to the memory cells MC and extending in the second direction (Y-direction).

Each memory cell MC may include a cell transistor cTR and an information storage structure DS that may function as an information storage device. In a memory such as a DRAM, the information storage structure DS may be a cell capacitor that may store information.

Each memory cell array region CA may further include back gate lines BG. Each back gate line of the back gate lines BG may be disposed between a pair of word lines WL disposed adjacently to each other in the second direction (Y-direction), among the word lines WL. Each back gate line BG may be disposed between the channel regions of the cell transistors cTR.

The second bank region BA2 in the second structure ST2 may include peripheral circuit regions PC. The peripheral circuit regions PC may be arranged in the first direction (X-direction) and the second direction (Y-direction). The peripheral circuit regions PC may overlap the memory cell array regions CA in a vertical direction (Z-direction). Each peripheral circuit region of the peripheral circuit regions PC may include a sense amplifier regions SAR1 and SAR2, a sub-word line driver region SWDR, and an inner peripheral region CONR. In each peripheral circuit region PC, the sense amplifier regions SAR1 and SAR2 may include a first sense amplifier region SAR1 and a second sense amplifier region SAR2 spaced apart from each other in the second direction (Y-direction). In each peripheral circuit region PC, the sub-word line driver region SWDR and the inner peripheral region CONR may be disposed between the first sense amplifier region SAR1 and the second sense amplifier region SAR2. In each peripheral circuit region PC, the inner peripheral region CONR may include a control circuit that may control the sense amplifiers of the sense amplifier regions SAR1 and SAR2 and the sub-word line driver of the sub-word line driver region SWDR.

The first direction (X-direction) and the second direction (Y-direction) may be perpendicular to each other. The first direction (X-direction) and the second direction (Y-direction) may be referred to as a horizontal direction, and the third direction (Z-direction) may be referred to as a vertical direction.

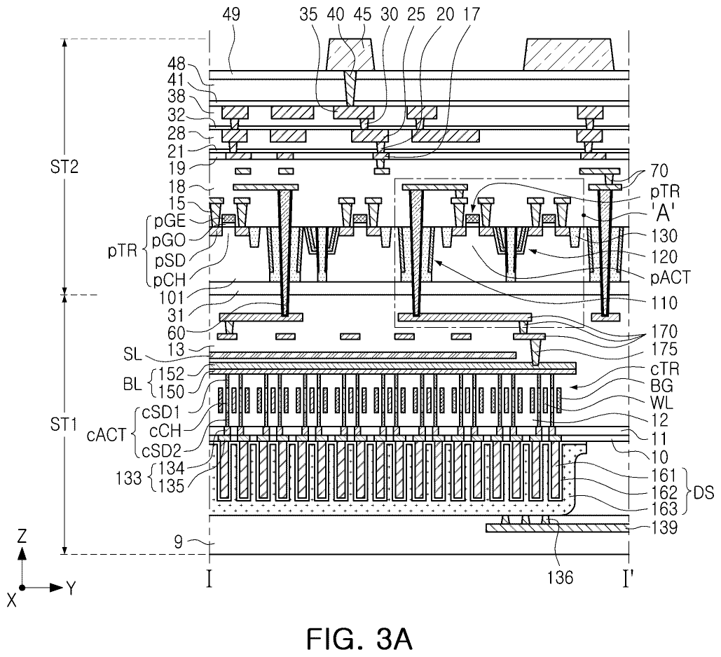

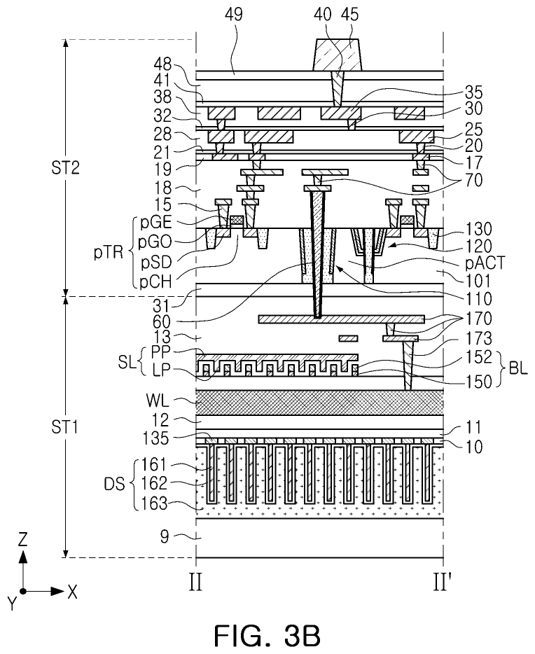

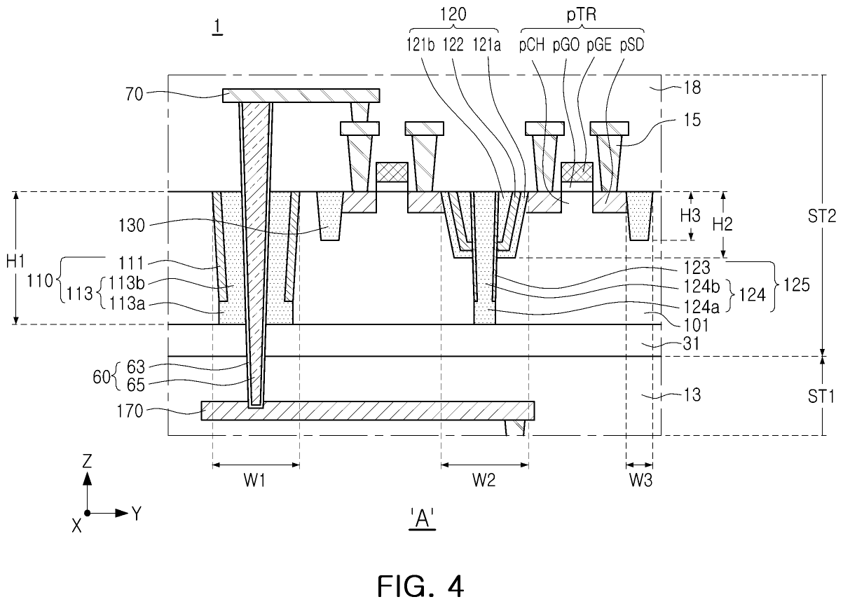

FIG. 3A is a cross-sectional view illustrating an example embodiment taken along line I-I′ of the semiconductor device of FIG. 2A. FIG. 3B is a cross-sectional view illustrating an example embodiment taken along line II-II′ of the semiconductor device of FIG. 2A. FIG. 4 is an enlarged view of a portion of an example embodiment of the semiconductor device illustrated in FIG. 3A. FIG. 4 is an enlarged view of region “A” of the semiconductor device illustrated in FIG. 3A.

Referring to FIG. 3A and FIG. 3B together with FIG. 2, the semiconductor device 1 may include a first structure ST1 and a second structure ST2 in contact with the first structure ST1. In an example, the first structure ST1 may include a cell transistor cTR in a memory cell array region CA, an information storage structure DS, and cell routing interconnection lines 170 electrically connected to the cell transistor cTR and the information storage structure DS.

The cell transistor cTR may include a word line WL extending in the first direction (X-direction), a bit line BL extending in the second direction (Y-direction), back gate lines BG extending in the first direction (X-direction), and cell active regions cACT.

The cell active regions cACT may include a semiconductor material that may be used as a channel of the transistor. The cell active regions cACT may include at least one of a silicon layer, an oxide semiconductor layer, or a two-dimensional material layer having semiconductor properties. For example, each cell active region of the cell active regions cACT may include single-crystal silicon or polysilicon. The cell active regions cACT may have a bar shape extending in the first direction (X-direction) and the second direction (Y-direction). Each cell active region cACT may include a first cell source/drain region cSD1, a second cell source/drain region cSD2 disposed on a lower level than that of the first cell source/drain region cSD1, and a cell channel region cCH between the first and second cell source/drain regions cSD1 and cSD2. The cell active regions cACT may be referred to as a cell semiconductor layer or a vertical channel layer. Each cell transistor of the cell transistors cTR may further include a cell gate dielectric layer in contact with a side surface of the cell channel region cCH and a side surface of the word line WL. A portion of the word line WL facing the cell channel region cCH may be a gate electrode. Each word line of the word lines WL may have a vertical length in the vertical direction (Z-direction) greater than a width in a second direction (Y-direction).

The back gate line BG may face a side surface of the cell channel region cCH. A back gate dielectric layer may be disposed between the back gate line BG and the cell channel region cCH. The cell channel region cCH may be disposed between the word line WL and the back gate line BG. A pair of cell active regions cACT adjacent to each other may be disposed between a pair of adjacent word lines WL. The back gate line BG may be disposed between the pair of cell active regions cACT. The back gate line BG may be a back gate electrode. The back gate line BG may control charges accumulated in the cell channel region cCH. The cell channel region cCH may be a floating body disposed between the first cell source/drain region cSD1 and the second cell source/drain region cSD2, and the back gate line BG may suppress or prevent the performance of the cell transistor cTR from being degraded due to a floating body effect, and may improve the performance of the cell transistor cTR.

The word lines WL may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi or combinations thereof, but the present invention is not limited thereto. Each word line WL may include a single layer or multiple layers of the aforementioned conductive materials. The back gate lines BG may include at least one conductive material. For example, each back gate line BG may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi or combinations thereof, but the present invention is not limited thereto. Each back gate line BG may include a single layer or multiple layers of the materials described above.

The bit lines BL may be electrically connected to the cell active regions cACT on the cell active regions cACT. For example, the bit lines BL may be electrically connected to the first cell source/drain region cSD1 of the cell active regions cACT.

Each bit line BL may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi or combinations thereof, but the present invention is not limited thereto. Each bit line BL may include a single layer or multiple layers of the aforementioned conductive materials. For example, each bit line BL may include a first conductive layer 150 and a second conductive layer 152 on the first conductive layer 150. The first conductive layer 150 may include doped silicon, and the second conductive layer 152 may include a conductive material having a lower resistivity than that of the doped silicon, among the aforementioned conductive materials.

The first structure ST1 may further include a shield conductive structure SL including line portions LP alternately arranged with bit lines BL and a connection portion PP extending from the line portions LP and covering upper surfaces of the bit lines BL. The connection portion PP may be plate-shaped. The shield conductive structure SL may be spaced apart from the bit lines BL. The shield conductive structure SL may screen capacitive coupling between the bit lines BL. For example, the shield conductive structure SL may reduce or block parasitic capacitance between the bit lines BL, thereby minimizing Resistive-Capacitive Delay (RC delay) of the bit lines BL.

The first structure ST1 may further include cell routing interconnection lines 170, word line contact plugs 173, and bit line contact plugs 175. The cell routing interconnection lines 170 may include interconnection lines and conductive vias connecting the interconnection lines. The word line contact plug 173 may electrically connect a word line WL and the cell routing interconnection lines 170. The bit line contact plug 175 may electrically connect the bit line BL and the cell routing interconnection lines 170.

The information storage structure DS may be at a lower vertical level than that of the word line WL. The information storage structure DS may include first electrodes 161 extending in a vertical direction (Z-direction), second electrodes 163 covering side surfaces and lower surfaces of the first electrodes 161, and a dielectric layer 162 between the first electrodes 161 and the second electrode 163.

The information storage structure DS may be cell capacitors capable of storing information in a memory such as a DRAM, but the present invention is not limited thereto. For example, the information storage structure DS may be an information storage structure of an MRAM or an information storage structure of an FeRAM.

The first structure ST1 may further include contact structures 133 electrically connecting the second cell source/drain region cSD2 and the first electrodes 161. Each contact structure of the contact structures 133 may include a plug portion 134 in contact with the cell active region cACT and a pad portion 135 below the plug portion 134. The information storage structures DS may be disposed below the pad portion 135.

The first structure ST1 may further include capacitor vias 136 below the second electrode 163 and a capacitor interconnection line 139 disposed below the capacitor vias 136 and extending to the outside of the information storage structure DS.

The first structure ST1 may further include a first insulating layer 9, a second insulating layer 10, a third insulating layer 11, a fourth insulating layer 12, and a fifth insulating layer 13.

The information storage structures DS may be disposed within the first insulating layer 9. The second insulating layer 10 may be disposed on side surfaces of the pad portions 135. The third insulating layer 11 may be disposed on side surfaces of the plug portions 134. The cell transistor cTR and the back gate lines BG may be disposed within the fourth insulating layer 12. The bit lines BL, the shield conductive structure SL, the word line contact plug 173, the bit line contact plug 175 and the cell routing interconnection lines 170 may be disposed within the fifth insulating layer 13.

The second structure ST2 may include a semiconductor body 101 including peripheral active regions pACT, first through-insulating patterns 110 penetrating through the semiconductor body 101, first device isolating patterns 120 defining the peripheral active regions pACT within the semiconductor body 101, second device isolating patterns 130, and second through-insulating patterns 125 penetrating through the first device isolating patterns 120.

The second structure ST2 may include a semiconductor body 101 including peripheral active regions pACT, a rear insulating layer 31 disposed below the semiconductor body 101, first and second device isolating patterns 120 and 130 defining the peripheral active regions pACT on the semiconductor body 101, first through-insulating patterns 110 penetrating through the semiconductor body 101, and second through-insulating patterns 125 penetrating through each first device isolating pattern 120.

The semiconductor body 101 may include a semiconductor material, such as a group IV semiconductor, a group III-V compound semiconductor, or a group II-VI compound semiconductor. For example, the group IV semiconductor may include silicon, germanium, and/or silicon-germanium. The semiconductor body 101 may include single crystal silicon. The semiconductor body 101 may have a thickness ranging from about 0.5 μm to about 2 μm, or about 0.75 μm to about 1.75 μm.

The first and second device isolating patterns 120 and 130 may define peripheral active regions pACT. The first device isolating patterns 120 may be disposed between peripheral transistors pTR, and the second device isolating pattern 130 may be disposed on one side of the peripheral transistor pTR.

The first device isolating patterns 120 may be spaced apart from the second device isolating patterns 130 in a horizontal direction. Each first device isolating pattern 120 and the second device isolating patterns 130 may have a width that may become narrower toward a lower portion thereof. A second width W2 of each first device isolating pattern 120 may be greater than a third width W3 of each second device isolating pattern 130. The second width W2 of the first device isolating pattern 120 may be a width of an upper surface of the first device isolating pattern 120 in the second direction (Y-direction). The third width W3 of the second device isolating pattern 130 may be a width of an upper surface of the second device isolating pattern 130 in the second direction (Y-direction).

A second height H2 of the first device isolating pattern 120 in the vertical direction (Z-direction) may be greater than a third height H3 of the second device isolating pattern 130 in the vertical direction (Z-direction). The first device isolating pattern 120 and the second device isolating pattern 130 have a trench shape buried from an upper surface to a lower surface of the semiconductor body 101. The first device isolating pattern 120 may have a structure in which the trench is penetrated by the second through-insulating pattern 125 described below.

The first device isolating pattern 120 may include a first device isolating insulating film 121a conformally covering a side surface and a bottom surface of the trench, a second device isolating insulating film 122 disposed on the first device isolating insulating film 121a, and a third device isolating insulating film 121b disposed on the second device isolating insulating film 122. The second device isolating insulating film 122 may be conformally disposed on the first device isolating insulating film 121a by corresponding to a surface profile of the first device isolating insulating film 121a. The second device isolating insulating film 122 may cover a side surface and a bottom surface of the first device isolating insulating film 121a according to the shape of the trench. The third device isolating insulating film 121b may be disposed by corresponding to the surface profile of the second device isolating insulating film 122. The third device isolating insulating film 121b may cover a side surface and a bottom surface of the second device isolating insulating film 122 according to the shape of the trench. In an example embodiment, the first device isolating insulating film 121a and the third device isolating insulating film 121b may include a first insulating material, and the second device isolating insulating film 122 may include a second insulating material different from the first insulating material. The first insulating material may include silicon oxide, and the second insulating material may include silicon nitride.

The second device isolating pattern 130 may include silicon oxide. However, the present invention is not limited thereto, and the second device isolating pattern 130 may include a second-first device isolating insulating film including silicon oxide, and a second-second device isolating insulating film disposed on the second-first device isolating insulating film and including silicon nitride.

Each of the first and second device isolating patterns 120 and 130 may be disposed in the semiconductor body 101 and may have an upper surface exposed from an upper surface of the semiconductor body 101.

Upper surfaces of the first and second device isolating patterns 120 and 130 (for example in Z-direction) may be coplanar with the upper surface of the semiconductor body 101. Lower surfaces of the first and second device isolating patterns 120 and 130 may be at a higher vertical level (with respect to Z-direction) than the lower surface of the semiconductor body 101. The lower surface of the first device isolating pattern 120 may be at a lower vertical level than the lower surface of the second device isolating pattern 130.

In this document, the first device isolating pattern 120 may be referred to as a wide device isolating pattern, and the second device isolating pattern 130 may be referred to as a narrow device isolating pattern.

The first through-insulating pattern 110 may penetrate through the semiconductor body 101. The first through-insulating pattern 110 may be spaced apart from the first and second device isolating patterns 120 and 130 in the horizontal direction.

An upper surface of the first through-insulating pattern 110 may be coplanar with the upper surface of the semiconductor body 101, and a lower surface of the first through-insulating pattern 110 may be coplanar with the lower surface of the semiconductor body 101.

The first through-insulating pattern 110 may include a first insulating pattern 113 including a first portion 113a adjacent to the rear insulating layer 31 and a second portion 113b disposed on the first portion 113a, and a second insulating pattern 111 disposed between a side surface of the second portion 113b of the first insulating pattern 113 and the semiconductor body 101. The second insulating pattern 111 may surround the second portion 113b of the first insulating pattern 113 on the first portion 113a of the first insulating pattern 113. In an example, a side surface of the first portion 113a of the first insulating pattern 113 may be in contact with the semiconductor body 101.

The first insulating pattern 113 may include a first insulating material, and the second insulating pattern 111 may include a second insulating material different from the first insulating material. In an example, the first insulating pattern 113 may include silicon oxide, and the second insulating pattern 111 may include silicon nitride.

A lower surface of the first portion 113a of the first insulating pattern 113 may be coplanar with the lower surface of the semiconductor body 101, and an upper surface of the second portion 113b of the first insulating pattern 113 and an upper surface of the second insulating pattern 111 may be coplanar with the upper surface of the semiconductor body 101.

The first through-insulating pattern 110 may have a width that becomes narrower as the first through-insulating pattern 110 moves downwardly. In an example, an inclination of a side surface of the second portion 113b of the first insulating pattern 113 may be greater than an inclination of a side surface of the first portion 113a of the first insulating pattern 113. For example, the second portion 113b of the first insulating pattern 113 of the first through-insulating pattern 110 may have a width that may become narrower toward a lower portion thereof, and the first portion 113a of the first insulating pattern 113 of the first through-insulating pattern 110 may have a width that may be constant in the vertical direction.

A vertical height of the first portion 113a of the first insulating pattern 113 may be less than a vertical height of the second portion 113b of the first insulating pattern 113.

A first width W1 of each of the first through-insulating patterns 110 may be greater than the second width W2 of each of the first device isolating patterns 120 and the third width W3 of each of the second device isolating patterns 130. In another example, the first width W1 of the first through-insulating pattern 110 may be substantially equal to or less than the second width W2 of the first device isolating pattern 120. The first width W1 of the first through-insulating pattern 110 may be a width of an upper surface of the first through-insulating pattern 110 in the second direction (Y-direction).

A first height H1 of each of the first through-insulating patterns 110 in the vertical direction may correspond to a height of the semiconductor body 101. In an example, the first height H1 of the first through-insulating pattern 110 may be greater than the second height H2 of the first device isolating pattern 120 and the third height H3 of the second device isolating pattern 130.

A lower surface of the second insulating pattern 111 of the first through-insulating pattern 110 may be at a lower vertical level with respect to Z-direction than that of lower surfaces of the first and second device isolating patterns 120 and 130.

The second through-insulating patterns 125 may penetrate through the first device isolating patterns 120 and the semiconductor body 101 below the first device isolating patterns 120.

Lower surfaces of the second through-insulating patterns 125 may be coplanar with the lower surface of the semiconductor body 101, and upper surfaces of the second through-insulating patterns 125 may be coplanar with the upper surface of the semiconductor body 101.

A width of each second through-insulating pattern 125 may be smaller than the first width W1 of each first through-insulating pattern 110. A width of the second through-insulating pattern 125 may be a width of an upper surface of the second through-insulating pattern 125 in the second direction (Y-direction).

The second through-insulating pattern 125 may include a third insulating pattern 124 including a third portion 124a adjacent to the rear insulating layer 31 and a fourth portion 124b disposed on the third portion 124a, and a fourth insulating pattern 123 disposed between a side surface of the fourth portion 124b of the third insulating pattern 124 and the semiconductor body 101. The fourth insulating pattern 123 of the second through-insulating pattern 125 may surround the fourth portion 124b of the third insulating pattern 124 of the second through-insulating pattern 125. In an example, a side surface of the third portion 124a of the third insulating pattern 124 may be in contact with the semiconductor body 101.

A lower surface of the third portion 124a of the third insulating pattern 124 may be coplanar with the lower surface of the semiconductor body 101, and an upper surface of the fourth portion 124b of the third insulating pattern 124 and an upper surface of the fourth insulating pattern 123 may be coplanar with the upper surface of the semiconductor body 101.

A lower surface of the fourth insulating pattern 123 may be disposed on a lower level than the lower surface of the first device isolating pattern 120.

The second through-insulating pattern 125 may have a width that may become narrower toward a lower portion thereof. In an example, an inclination of a side surface of the fourth portion 124b of the third through-insulating pattern 124 may be greater than an inclination of a side surface of the third portion 124a of the third through-insulating pattern 124. For example, the fourth portion 124b of the third through-insulating pattern 124 may have a width that may narrower toward a lower portion thereof, and the third portion 124a of the third through-insulating pattern 124 may have a width that may be constant in the vertical direction.

In an example embodiment, a vertical height of the first portion 113a of the first through-insulating pattern 110 may be substantially the same as a vertical height of the third portion 124a of the second through-insulating pattern 125. However, the present invention is not limited thereto, and in another example embodiment, a vertical height of the first portion 113a of the first through-insulating pattern 110 may be greater than a vertical height of the third portion 124a of the second through-insulating pattern 125.

A vertical height of the third portion 124a of the third insulating pattern 124 may be less than a vertical height of the fourth portion 124b of the third insulating pattern 124. A portion of an outer surface of the fourth insulating pattern 123 may be in contact with the first device isolating pattern 120, and the remainder of the outer surface of the fourth insulating pattern 123 may be in contact with the semiconductor body 101.

The second structure ST2 may include a rear insulating layer 31 covering a lower surface of the semiconductor body 101 and lower surfaces of the first and second through-insulating patterns 110 and 125. In an example embodiment, a lower surface of the rear insulating layer 31 may be bonded to an upper surface of the fifth insulating layer 13. Accordingly, an upper surface of the first structure ST1 and a lower surface of the second structure ST2 may be bonded to form a bonding surface.

The second structure ST2 may further include a peripheral transistor pTR disposed on the semiconductor body 101, through-vias 60 penetrating through each first through-insulating pattern 110, and peripheral routing interconnection lines 70.

Each of the peripheral transistors pTR may include peripheral source/drain regions pSD disposed within a peripheral active region pACT, peripheral channel regions pCH between the peripheral source/drain regions pSD, and peripheral gates pGO and pGE on the peripheral channel regions pCH. The peripheral gates pGO and pGE may include a peripheral gate dielectric layer pGO, and a peripheral gate pGE on the peripheral gate dielectric layer pGO. The peripheral transistors pTR may include an NMOS transistor and a PMOS transistor. When the peripheral transistor pTR is the NMOS transistor, the peripheral source/drain regions pSD may have an N-type conductivity, and when the peripheral transistor pTR is the PMOS transistor, the peripheral source/drain regions pSD may have a P-type conductivity. In an example embodiment, the peripheral transistor pTR may include a transistor of a sub-word line driver and a transistor of a sense amplifier.

A first device isolating pattern 120 may be disposed between the peripheral transistors pTR. For example, the first and second peripheral transistors may be spaced apart from each other in the horizontal direction with the first device isolating pattern 120 interposed therebetween. The first peripheral transistor may include first and second source/drain regions disposed within a first peripheral active region, among peripheral active regions pACT, a first peripheral channel region between the first and second source/drain regions, and a first peripheral gate disposed on the first peripheral channel region. The second peripheral transistor on an opposite side of the first device isolating pattern with respect to the first peripheral transistor, may include third and fourth source/drain regions disposed within a second peripheral active region, among peripheral active regions pACT, a second peripheral channel region between the third and fourth source/drain regions, and a second peripheral gate disposed on the second peripheral channel region. The first peripheral active region and the second peripheral active region may be defined by the first device isolating pattern 120, and a side surface of the first peripheral active region may be defined by the first device isolating pattern 120 and/or the second device isolating pattern 130.

Each through-via 60 may extend over an upper surface of the first through-insulating pattern 110 and may be electrically connected to peripheral routing interconnection lines 70 within a lower insulating structure 18 on the first through-insulating pattern 110. The through-vias 60 may penetrate through a portion of the fifth insulating layer 13 of the first structure ST1 disposed below the rear insulating layer 31 and may be electrically connected to cell routing interconnection lines 170 within the fifth insulating layer 13.

The through-vias 60 may include a conductive pillar 65 and a conductive barrier layer 63 covering side surfaces and bottom surfaces of the conductive pillar 65. The conductive pillar 65 may include a metallic material such as tungsten, aluminum, or copper. The conductive barrier layer 63 may include a metal nitride such as titanium nitride, tantalum nitride, or tungsten nitride.

The peripheral routing interconnection lines 70 may be electrically connected to vertical plugs 15 and through-vias 60 connected to the peripheral source/drain regions pSD. The peripheral routing interconnection lines 70 may include interconnection lines and conductive vias connecting the interconnection lines. The peripheral routing interconnection lines 70 may be electrically connected to the peripheral transistor pTR and/or the through-vias 60.

The second structure ST2 may further include a lower insulating structure 18, and a first interlayer insulating layer 19, a first barrier insulating layer 21, a second interlayer insulating layer 28, a second barrier insulating layer 32, a third interlayer insulating layer 38, a third barrier insulating layer 41, a fourth interlayer insulating layer 48 and a fourth barrier insulating layer 49, sequentially stacked on the lower insulating structure 18 in that order.

The first, second, third, and fourth barrier insulating layers 21, 32, 41 and 49 may include a material different from that of the first, second, third, and fourth interlayer insulating layers 19, 28, 38 and 48.

The peripheral routing interconnection lines 70 and the vertical plugs 15 may be disposed within the lower insulating structure 18. The first interlayer insulating layer 19 may be disposed on an upper surface of the lower insulating structure 18 and may surround side surfaces of first horizontal interconnection lines 17 connected to the peripheral routing interconnection lines 70.

First vertical vias 20 may be disposed on the first horizontal interconnection lines 17, and second horizontal interconnection lines 25 may be disposed on the first vertical vias 20. The first vertical vias 20 may penetrate through the first barrier insulating layer 21 and a portion of the second interlayer insulating layer 28, and may electrically connect the first horizontal interconnection lines 17 and the second horizontal interconnection lines 25. The second interlayer insulating layer 28 may surround side surfaces of the second horizontal interconnection lines 25.

Second vertical vias 30 may be disposed on the second horizontal interconnection lines 25, and third horizontal interconnection lines 35 may be disposed on the second vertical vias 30. The second vertical vias 30 may penetrate through the second barrier insulating layer 32 and a portion of the third interlayer insulating layer 38, and may electrically connect the second horizontal interconnection lines 25 and the third horizontal interconnection lines 35. The third interlayer insulating layer 38 may surround side surfaces of the third horizontal interconnection lines 35.

Third vertical vias 40 may be disposed on the third horizontal interconnection lines 35, and upper interconnection lines 45 may be disposed on the third vertical vias 40. The third vertical vias 40 may electrically connect the third horizontal interconnection lines 35 and the upper interconnection lines 45 by penetrating through the third barrier insulating layer 41, the fourth interlayer insulating layer 48 and the fourth barrier insulating layer 49. The upper interconnection lines 45 may be disposed on the fourth barrier insulating layer 49.

Each of the first, second and third horizontal interconnection lines 17, 25 and 35, the upper interconnection lines 45, and the first, second and third vertical vias 20, 30 and 40 may be formed of Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, and/or combinations thereof, but is not limited thereto. However, the present invention is not limited thereto, and each of the first, second and third horizontal interconnection lines 17, 25 and 35, the upper interconnection lines 45, and the first, second and third vertical vias 20, 30 and 40 may include a single layer or multiple layers of the aforementioned materials.

A semiconductor device 1 according to example embodiments of the present disclosure may include a first through-insulating pattern 110 penetrating through a semiconductor body 101, a first device isolating pattern 120, and a second through-insulating pattern 125 penetrating through the semiconductor body 101 disposed below the first device isolating pattern 120, and may secure a portion capable of polishing the semiconductor body 101 in the vertical direction in a polishing process of the semiconductor body 101 during a manufacturing process of the semiconductor device through the first portion 113a of the first through-insulating pattern 110 and the third portion 124a of the second through-insulating pattern 125. Accordingly, a thickness of the semiconductor body 101 may be minimized, thereby providing a semiconductor device having a reduced size. Additionally, in the polishing process of the semiconductor body 101, a portion polished in the vertical direction in the semiconductor body 101 may be secured to improve the problem of dispersion deterioration in a bonding process, subsequent process, thereby providing a semiconductor device having improved reliability.

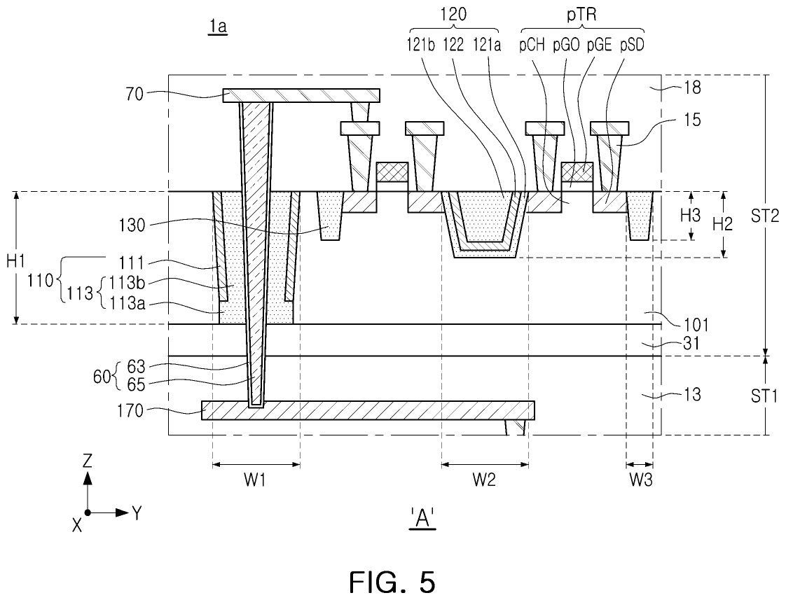

FIGS. 5 to 9 are enlarged views of portions of other example embodiments of the semiconductor device illustrated in FIG. 3A.

Referring to FIG. 5, a semiconductor device 1a is a semiconductor device in which the second through-insulating pattern 125 of the semiconductor device 1 of FIG. 4 is omitted, and the remaining components except for the second through-insulating pattern 125 may be identical to or correspond to the components illustrated in FIG. 1. The first device isolating pattern 120 of the semiconductor device 1a may have a trench structure.

The semiconductor device 1a according to an example embodiment of the present disclosure may include a first through-insulating pattern 110 penetrating through the semiconductor body 101. Accordingly, through the first portion 113a of the first through-insulating pattern 110, in a polishing process of the semiconductor body 101 during the manufacturing process of the semiconductor device, a portion capable of polishing the semiconductor body 101 in the vertical direction may be secured.

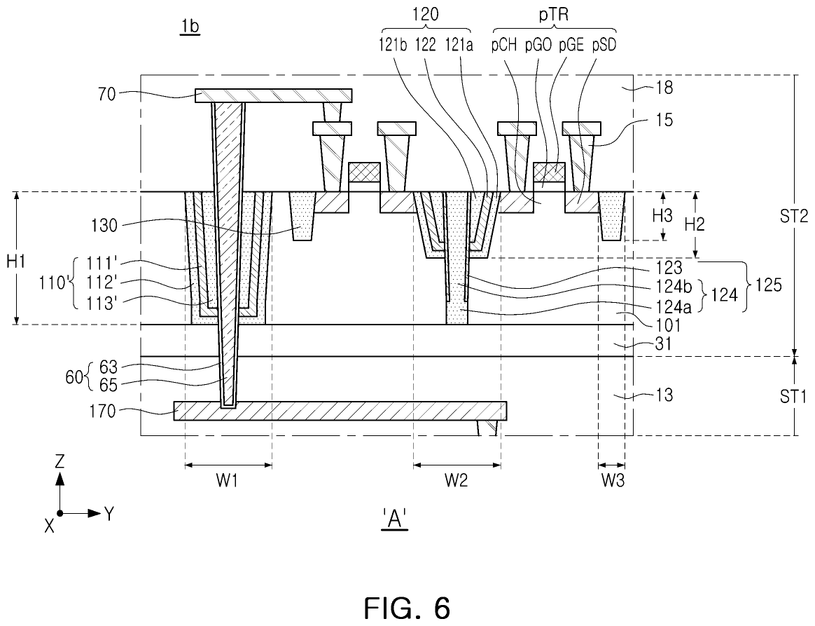

Referring to FIG. 6, a semiconductor device 1b may include a first through-insulating pattern 110′ penetrating through the semiconductor body 101 and a second through-insulating pattern 125 penetrating a first device isolating pattern 120 and the semiconductor body 101 disposed below the first device isolating pattern 120. The remaining components illustrated in FIG. 6, excluding the first through-insulating pattern 110′, may be identical to or correspond to the components illustrated in FIG. 4.

The first through-insulating pattern 110′ may have a width that may become narrower toward a lower portion thereof. The first through-insulating pattern 110′ may include a first-first insulating pattern 112′ having a side surface in contact with the semiconductor body 101 and a lower surface in contact with the rear insulating layer 31, a first-second insulating pattern 111′ disposed on the first-first insulating pattern 112′ according to a surface profile of the first-first insulating pattern 112′, and a first-third insulating pattern 113′ disposed on the first-second insulating pattern 111′ according to a surface profile of the first-second insulating pattern 111′.

In an example embodiment, the first-first insulating pattern 112′ and the first-third insulating pattern 113′ may include a first insulating material, and the first-second insulating pattern 111′ may include a second insulating material different from the first insulating material. For example, the first-first insulating pattern 112′ and the first-third insulating pattern 113′ may include silicon oxide, and the first-second insulating pattern 111′ may include silicon nitride.

A semiconductor device 1b according to an example embodiment of the present disclosure may include a first device isolating pattern 120 and a second through-insulating pattern 125 penetrating through the semiconductor body 101 below the first device isolating pattern 120. Accordingly, through the third portion 124a of the second through-insulating pattern 125, a portion capable of polishing the semiconductor body 101 in the vertical direction in a polishing process of the semiconductor body 101 may be secured during a manufacturing process of the semiconductor device.

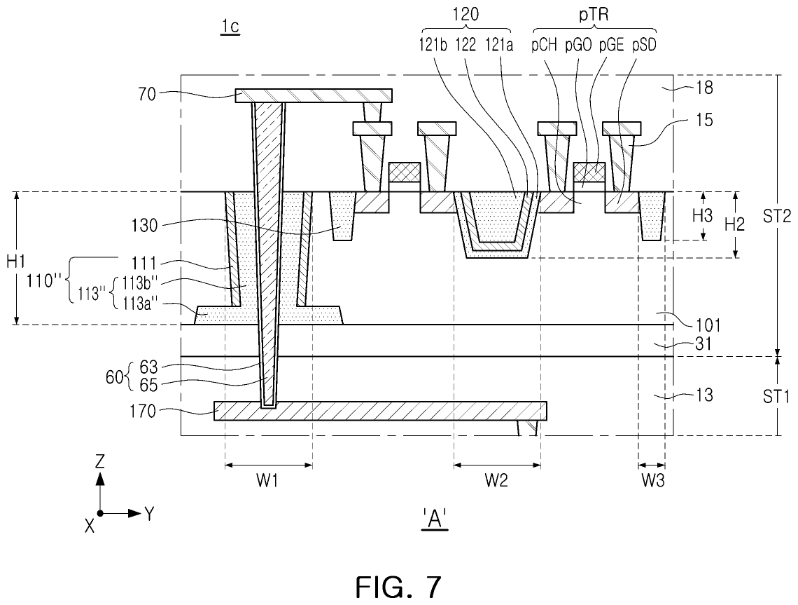

Referring to FIG. 7, a semiconductor device 1c may include a first through-insulating pattern 110′ penetrating through the semiconductor body 101, and may be a semiconductor device in which the second through-insulating pattern 125 of the semiconductor device 1 of FIG. 4 is omitted. The remaining components illustrated in FIG. 7 except for the first through-insulating pattern 110′ may be identical to or correspond to the components illustrated in FIG. 5.

The first through-insulating pattern 110′ may include a first insulating pattern 113′ including a first portion 113a′ adjacent to the rear insulating layer 31 and a second portion 113b′ disposed on the first portion 113a′, and a second insulating pattern 111 disposed between a side surface of the second portion 113b′ of the first insulating pattern 113′ and the semiconductor body 101. A portion of an upper surface of the first portion 113a′ of the first insulating pattern 113′ may be in contact with the semiconductor body 101. An upper surface of the first portion 113a′ of the first insulating pattern 113′ may include a first region in which the second portion 113b′ of the first insulating pattern 113′ and the second insulating pattern 111 surrounding the second portion 113b′ are disposed (or formed), and a second region in contact with the semiconductor body 101 in addition to the first region. In example embodiments, the second insulating pattern 111 is between a second portion 113b′ of the first insulating pattern 113′ and the semiconductor body 101.

The first portion 113a′ of the first insulating pattern 113′ may have a structure expanded in the horizontal direction based on a portion vertically overlapping the second portion 113b′ of the first insulating pattern 113′. In an example, the first portion 113a′ of the first insulating pattern 113′ may have a width that may become wider toward a lower portion thereof.

A vertical height of the first portion 113a′ of the first insulating pattern 113′ may be smaller than a vertical height of the second portion 113b′ of the first insulating pattern 113′.

The semiconductor device 1c according to an example embodiment of the present disclosure may include a first through-insulating pattern 110′ penetrating through the semiconductor body 101. Accordingly, in a polishing process of the semiconductor body 101 during the manufacturing process of the semiconductor device, the first portion 113a′ of the first through-insulating pattern 110′ may be utilized to secure a portion in which the semiconductor body 101 can may polished in the vertical direction.

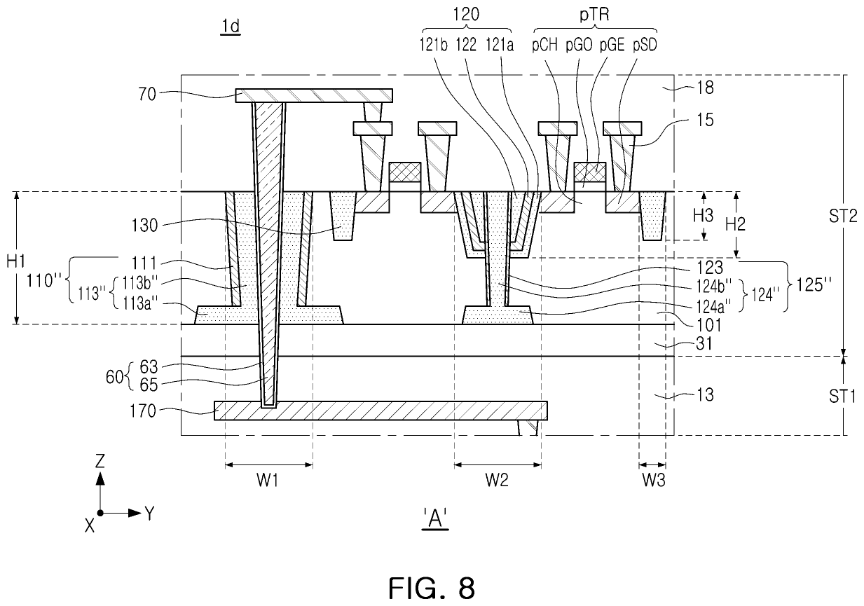

Referring to FIG. 8, a semiconductor device 1d may include a first through-insulating pattern 110′ penetrating through the semiconductor body 101, a first device isolating pattern 120 in the semiconductor body 101, and a second through-insulating pattern 125′ penetrating through the semiconductor body 101 disposed below the first device isolating pattern 120. The remaining components illustrated in FIG. 8, except for the second through-insulating pattern 125′, may be identical to or correspond to the components illustrated in FIG. 7.

The first through-insulating pattern 110′ of the semiconductor device 1d may correspond to the first through-insulating pattern 110′ of the semiconductor device 1c of FIG. 7.

The second through-insulating pattern 125′ may include a third insulating pattern 124′ including a third portion 124a′ adjacent to the rear insulating layer 31 and a fourth portion 124b′ disposed on the third portion 124a′, and a fourth insulating pattern 123 disposed between a side surface of the fourth portion 124b′ of the third insulating pattern 124′ and the semiconductor body 101. A portion of an upper surface of the third portion 124a′ of the third insulating pattern 124′ may be in contact with the semiconductor body 101. In an example, an upper surface of the third portion 124a′ of the third insulating pattern 124′ may include a third region in which the fourth portion 124b′ of the third insulating pattern 124′ and a fourth insulating pattern 123 surrounding the fourth portion 124b′ are disposed (or formed) and a fourth region in contact with the semiconductor body 101, in addition to the third region.

The third portion 124a′ of the third insulating pattern 124′ may have a structure expanded in the horizontal direction based on a portion vertically overlapping the fourth portion 124b′. In an example, the third portion 124a′ of the third insulating pattern 124′ may have a width that may become wider toward a lower portion thereof. In an example embodiment, a width of the first portion 113a′ of the first through-insulating pattern 110′ may be greater than a width of the third portion 124a′ of the second through-insulating pattern 125′.

In an example embodiment, a vertical height of the first portion 113a′ of the first through-insulating pattern 110′ may be substantially the same as a vertical height of the third portion 124a′ of the second through-insulating pattern 125′. However, the present invention is not limited thereto, and in another example embodiment, a vertical height of the first portion 113a′ of the first through-insulating pattern 110′ may be greater than a vertical height of the third portion 124a′ of the second through-insulating pattern 125′.

In another example embodiment, the semiconductor device may include a first through insulating pattern 110′ and a second through-insulating pattern 125′ of the semiconductor device 1b of FIG. 6. In this case, in a polishing process of the semiconductor body 101 during the manufacturing process of the semiconductor device, the third portion 124a′ of the second through-insulating pattern 125′ may be utilized to secure a portion capable of polishing the semiconductor body 101 in the vertical direction.

The semiconductor device 1c according to an example embodiment of the present disclosure may include a first through-insulating pattern 110′ penetrating through the semiconductor body 101, a first device isolating pattern 120, and a second through-insulating pattern 125′ penetrating through the semiconductor body 101. Accordingly, in the polishing process of the semiconductor body 101 during the manufacturing process of the semiconductor device, the first portion 113a′ of the first through-insulating pattern 110′ and the third portion 124a′ of the second through-insulating pattern 125′ may be utilized to secure a portion capable of vertically polishing the semiconductor body 101.

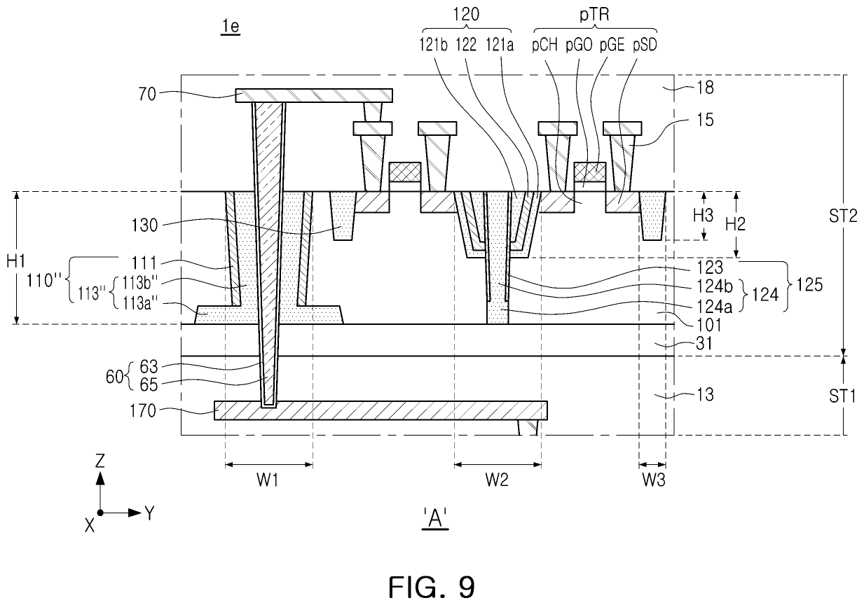

Referring to FIG. 9, a semiconductor device 1e may include a first through-insulating pattern 110′ penetrating through the semiconductor body 101 and a second through-insulating pattern 125 penetrating through a first device isolating pattern 120 and the semiconductor body 101 disposed below the first device isolating pattern 120. The first through-insulating pattern 110′ of the semiconductor device 1e may correspond to the first through-insulating pattern 110′ of the semiconductor device 1c of FIG. 7, and the second through-insulating pattern 125 may correspond to the second through-insulating pattern 125 of the semiconductor device 1 of FIG. 4.

The semiconductor device 1e according to an example embodiment of the present disclosure may include a first through-insulating pattern 110′ penetrating through the semiconductor body 101, a first device isolating pattern 120, and a second through-insulating pattern 125 penetrating through the semiconductor body 101. Accordingly, in a polishing process of the semiconductor body 101 during the manufacturing process of the semiconductor device, the first portion 113a′ of the first through-insulating pattern 110′ and a third portion 125a of the second through-insulating pattern 125 may be utilized to secure a portion capable of vertically polishing the semiconductor body 101.

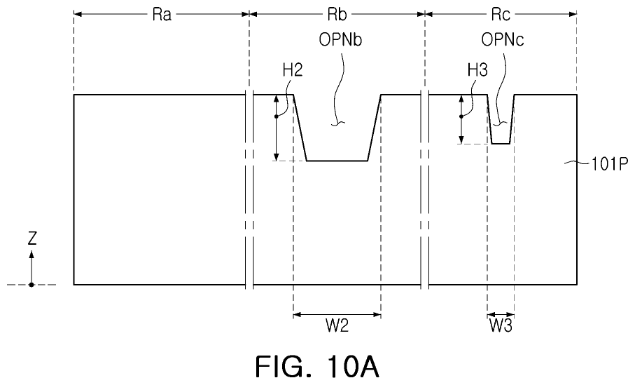

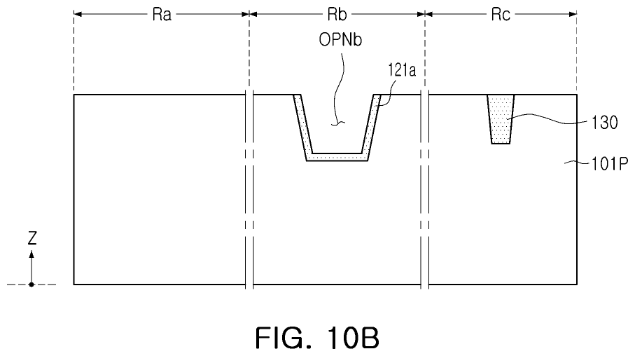

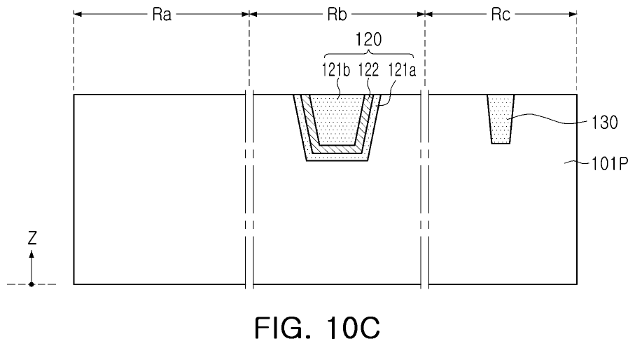

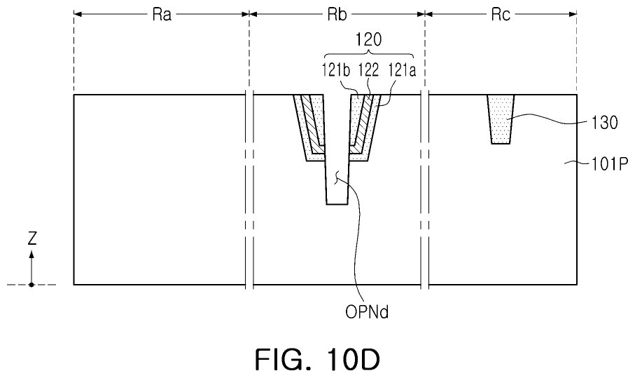

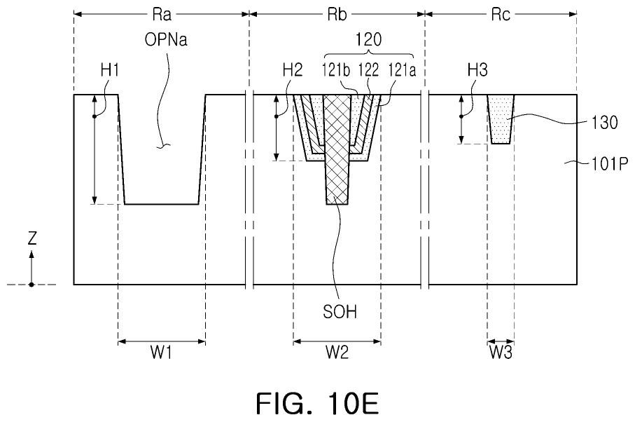

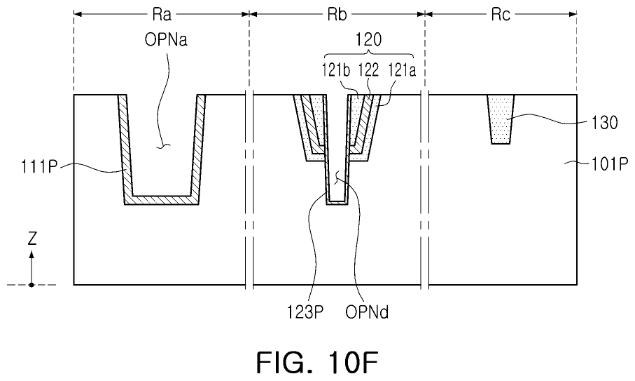

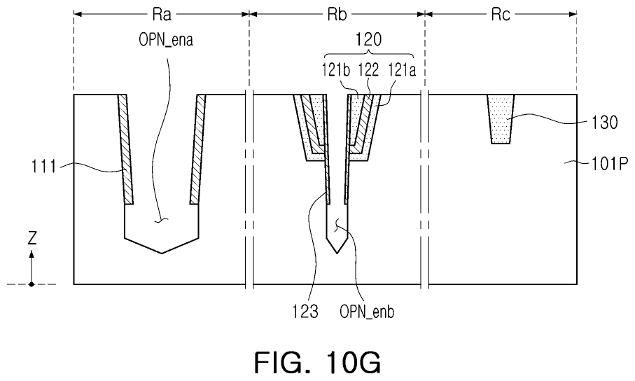

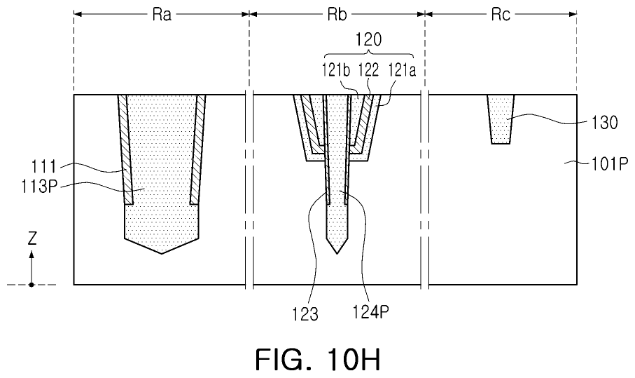

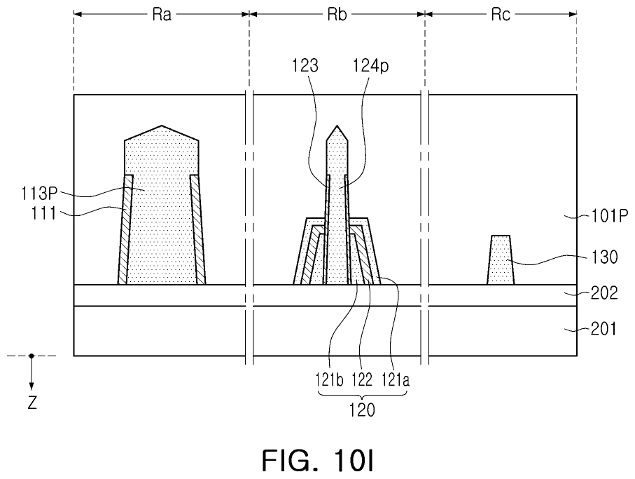

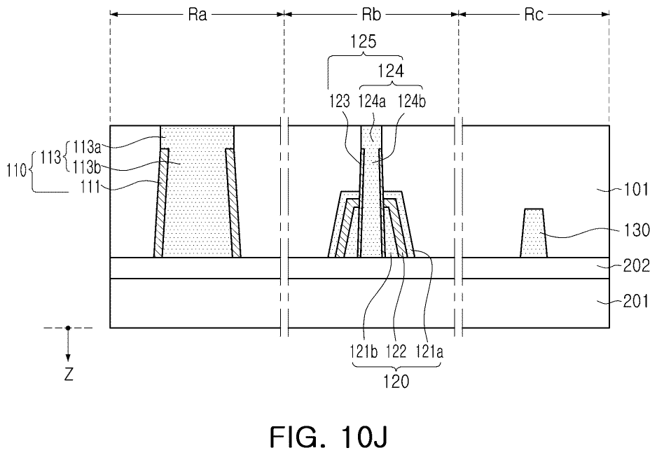

FIGS. 10A to 10J are views illustrating methods of manufacturing a semiconductor device according to example embodiments of the present disclosure.

Referring to FIG. 10A, a preliminary semiconductor body 101P may include a first region Ra, a second region Rb, and a third region Rc, spaced apart from each other, in the horizontal direction. The first region Ra may be a region in which the first through-insulating pattern 110 of FIG. 3A is formed, the second region Rb may be a region in which the first device isolating pattern 120 of FIG. 3B is formed, and the third region Rc may be a region in which the second device isolating pattern 130 of FIG. 3B is formed.

In the second region Rb, the preliminary semiconductor body 101P may be etched to form a second trench OPNb, and in the third region Rc, the preliminary semiconductor body 101P may be etched to form a third trench OPNc. Bottom surfaces of the second trench OPNb and the third trench OPNc may be formed within the preliminary semiconductor body 101P. In an example, a second width W2 of the second trench OPNb may be greater than a third width W3 of the third trench OPNc, and a second height H2, which is an etching depth of the second trench OPNb, may be greater than a third height H3, which is an etching depth of the third trench OPNc.

Referring to FIG. 10B, a first insulating material may be formed in the second trench OPNb of the second region Rb and the third trench OPNc of the third region Rc. The first insulating material may be formed to correspond to a surface profile of the second trench OPNb of the second region Rb, so that a first device isolating insulating film 121a may be formed. The first insulating material may fill the third trench OPNc of the third region Rc to form a second device isolating pattern 130. In an example, the first insulating material may include silicon oxide. The first device isolating insulating film 121a and the second device isolating pattern 130 may be formed in a deposition process of the first insulating material, for example, at least one of a chemical vapor deposition (CVD), a plasma enhanced chemical vapor deposition (PECVD), an atomic layer deposition (ALD), or a plasma enhanced atomic layer deposition (PEALD).

Referring to FIG. 10C, a first device isolating pattern 120 may be formed by sequentially forming a second device isolating insulating film 122 and a third device isolating insulating film 121b on a first device isolating insulating film 121a. The second device isolating insulating film 122 may be formed of an insulating material distinct from the third device isolating insulating film 121b. For example, the second device isolating insulating film 122 may include silicon nitride, and the third device isolating insulating film 121b may include silicon oxide. The second device isolating insulating film 122 and the third device isolating insulating film 121b may be formed by the deposition process mentioned above.

Referring to FIG. 10D, a fourth trench OPNd penetrating through the first device isolating pattern 120 may be formed. A bottom surface of the fourth trench OPNd may be formed within the preliminary semiconductor body 101P. A bottom surface of the fourth trench OPNd may be formed on a vertical level lower than the lower surface of the first device isolating pattern 120 in Z-direction. In an example, a width of the fourth trench OPNd in the horizontal direction may be smaller than a width of the first device isolating pattern 120.

Referring to FIG. 10E, the preliminary semiconductor body 101P may be etched in the first region Ra to form a first trench OPNa. A bottom surface of the first trench OPNa may be formed within the preliminary semiconductor body 101P. A mask film SOH filling the fourth trench OPNd may be formed. The mask film SOH may include a spin on hardmask, but the present invention is not limited thereto.

A first width W1 of the first trench OPNa may be greater than a third width W3 of the second device isolating pattern 130, and a first height H1, which is an etching depth of the first trench OPNa, may be greater than a second height H2 of the first device isolating pattern 120 and a third height H3 of the second device isolating pattern 130. In an example, a first height H1 of the first trench OPNa may be substantially the same as a height of the fourth trench OPNd in the vertical direction, but the present invention is not limited thereto. For example, the first height H1 of the first trench OPNa may be greater than the height of the fourth trench OPNd in the vertical direction.

Referring to FIG. 10F, the mask film SOH in the fourth trench OPNd of FIG. 10E may be removed, a first insulating film 111P may be formed in the first trench OPNa of the first region Ra, and a second insulating film 123P may be formed in the fourth trench OPNd of the second region Rb. The first insulating film 111P may correspond to a surface profile of the first trench OPNa and may be formed conformally. The second insulating film 123P may correspond to a surface profile of the fourth trench OPNd and may be formed conformally. The first and second insulating films 111P and 123P may include the same insulating material, for example, silicon nitride. The first and second insulating films 111P and 123P may be formed by at least one of chemical vapor deposition (CVD), plasma enhanced chemical vapor deposition (PECVD), atomic layer deposition (ALD), or plasma enhanced atomic layer deposition (PEALD).

Referring to FIG. 10G, a bottom surface of the first insulating film 111P in the first trench OPNa of FIG. 10F may be removed to form a second insulating pattern 111, and a bottom surface of the second insulating film 123P in the fourth trench OPNd may be removed to form a fourth insulating pattern 123. The second insulating pattern 111 in the first region Ra may be used as a barrier film, so that the preliminary semiconductor body 101P exposed in a lower portion of the second insulating pattern 111 may be etched to form a first expansion trench OPN_ena. The fourth insulation pattern 123 in the second region Rb may be used as a barrier film, so that the preliminary semiconductor body 101P exposed in a lower portion of the fourth insulation pattern 123 may be etched to form a second expansion trench OPN_enb.

A bottom surface of the first insulation film 111P in the first trench OPNa and a bottom surface of the second insulation film 123P in the fourth trench OPNd may be removed in a wet etching process.

A shape of a bottom surface of the first expansion trench OPN_ena and a shape of a bottom surface of the second expansion trench OPN_enb may have an angular shape, but the present invention is not limited thereto, and in another example, the shape of the bottom surface of the first expansion trench OPN_ena and the shape of the bottom surface of the second expansion trench OPN_enb may have a round shape.

Referring to FIG. 10H, a first insulating material may be filled in the first expansion trench OPN_ena of the first region Ra to form a first preliminary insulating pattern 113P, and a third preliminary insulating pattern 124P may be formed by filling the first insulating material in the second expansion trench OPN_enb of the second region Rb. The first insulating material may be silicon oxide.

Referring to FIG. 10I, an upper surface of the preliminary semiconductor body 101P with the upper surface of the first device isolating pattern 120 exposed may be flipped to face downwardly, and then, an adhesive layer 202 and a dummy wafer 201 in a lower portion of the adhesive layer 202 may be formed to cover the first preliminary insulating pattern 113P, the second insulating pattern 111, the third preliminary insulating pattern 124P and the fourth insulating pattern 123. As used herein, the term “dummy” is used to refer to a component that has the same or similar structure and shape as other components but does not have a substantial function and exists only as a pattern in the device. The dummy wafer 201 may be a support member on which a polishing process of the preliminary semiconductor body 101P is performed. The dummy wafer 201 may be introduced as a bare silicon wafer. The dummy wafer 201 may include a wafer of a material other than a semiconductor material having a wafer shape, for example, a sapphire wafer, a silicon on insulator (SOI) wafer, a wafer of an insulating material, or a wafer of a dielectric material.

Referring to FIG. 10J, a semiconductor body 101 may be formed through a polishing process on the preliminary semiconductor body 101P so as to expose an upper surface of the first preliminary insulating pattern 113P and an upper surface of the third preliminary insulating pattern 124P of FIG. 10I. The polishing process may be an etch back or Chemical Mechanical Polishing (CMP) process for planarization. The first insulating pattern 113 may be formed in a polishing process for the first preliminary insulating pattern 113P in contact with the preliminary semiconductor body 101P so as to expose the upper surface of the first preliminary insulating pattern 113P, and the third insulating pattern 124 may be formed in a polishing process for the third preliminary insulating pattern 124P in contact with the preliminary semiconductor body 101P so as to expose the upper surface of the third preliminary insulating pattern 124P. In an example, the upper surface of the first preliminary insulating pattern 113P having a maximum width may be exposed in a polishing process for the first preliminary insulating pattern 113P, and the upper surface of the third preliminary insulating pattern 124P having a maximum width may be exposed in a polishing process for the third preliminary insulating pattern 124P.

The first insulating pattern 113 may include a first portion 113a having a side surface in contact with the semiconductor body 101 and a second portion 113b extending from the first portion 113a and having a side surface in contact with the second insulating pattern 111. The third insulating pattern 124 may include a third portion 124a having a side surface in contact with the semiconductor body 101 and a fourth portion 124b extending from the third portion 124a and having a side surface in contact with the fourth insulating pattern 123.

After the polishing process for the preliminary semiconductor body 101P, a process of forming a rear insulating layer 31 of FIG. 3A and bonding the rear insulating layer 31 to the first structure ST1 may be performed.

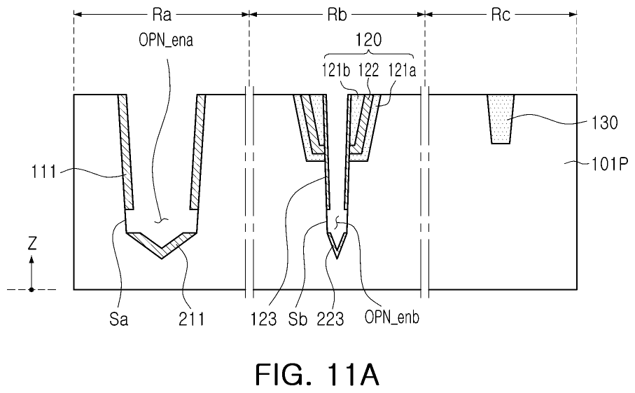

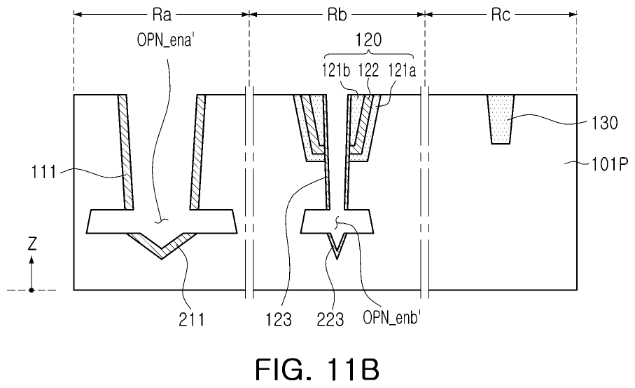

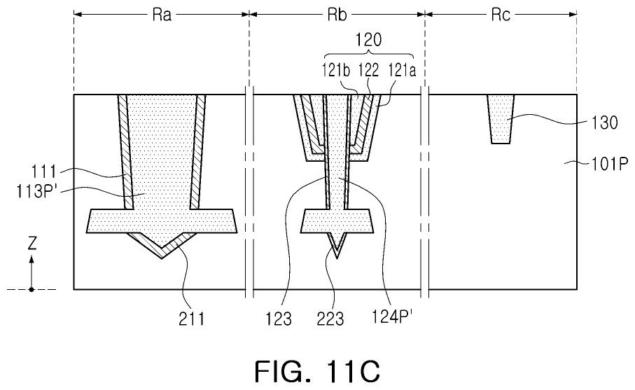

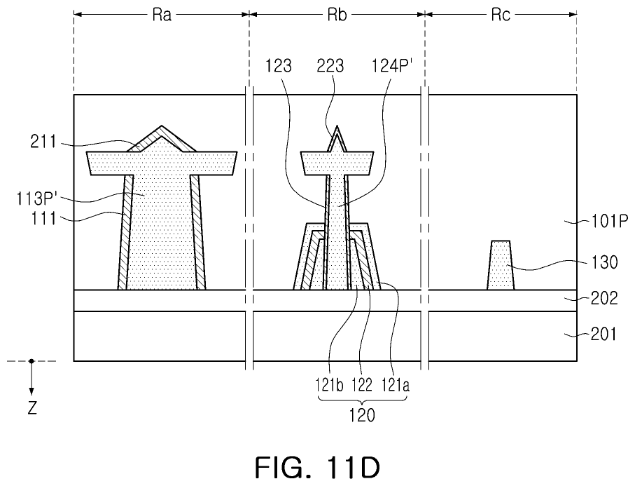

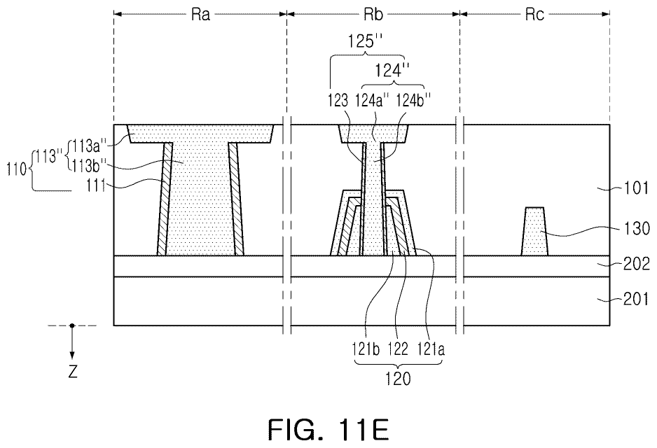

FIGS. 11A to 11E are views illustrating a method of manufacturing a semiconductor device according to another example embodiment of the present disclosure. FIGS. 11A to 11E are views illustrating a method of manufacturing a semiconductor device sequentially performed after the process according to FIGS. 10A to 10G.

Referring to FIG. 11A, a first partial pattern 211 may be formed on a bottom surface of a first expansion trench OPN_ena of a first region Ra, and a second partial pattern 223 may be formed on a bottom surface of a second expansion trench OPN_enb of a second region Rb. A preliminary semiconductor body 101P may be exposed through a side surface Sa of the first expansion trench OPN_ena and a side surface Sb of the second expansion trench OPN_enb.

In an example embodiment, the first partial pattern 211 and the second partial pattern 223 may be formed in a Physical Vapor Deposition (PVD) process, and the first partial pattern 211 and the second partial pattern 223 may include silicon nitride. However, the present invention is not limited thereto.

In another example embodiment, the first partial pattern 211 and the second partial pattern 223 may be formed by an ion implantation process, and the first partial pattern 211 and the second partial pattern 223 may include at least one of P-type impurities or N-type impurities. The P-type impurities may include boron (B), gallium (Ga), and/or indium (In), and the N-type impurities may include phosphorus (P), arsenic (As), and/or antimony (Sb).

Referring to FIG. 11B, the second insulating pattern 111 and the first partial pattern 211 may be used as barrier films, so that the preliminary semiconductor body 101P exposed to the side surface Sa of the first expansion trench OPN_ena of FIG. 11A may be etched horizontally to form a third expansion trench OPN_ena′. The fourth insulating pattern 123 and the second partial pattern 223 may be used as barrier films, so that the preliminary semiconductor body 101P exposed to the side surface Sb of the second expansion trench OPN_enb of FIG. 11A may be etched in the horizontal direction, thereby forming a fourth expansion trench OPN_enb'.

Referring to FIG. 11C, a first insulating material may be filled in the third expansion trench OPN_ena′ of the first region Ra to form a first preliminary insulating pattern 113P′, and the first insulating material may be filled in the fourth expansion trench OPN_enb′ of the second region Rb to form a third preliminary insulating pattern 124P′. The first insulating material may be silicon oxide.

Referring to FIG. 11D, the upper surface of the preliminary semiconductor body 101P with the upper surface of the first device isolating pattern 120 exposed may be flipped to face downwardly, and then, an adhesive layer 202 and a dummy wafer 201 in a lower portion of the adhesive layer 202 may be formed to cover the first preliminary insulating pattern 113P′, the second insulating pattern 111, the third preliminary insulating pattern 124P′ and the fourth insulating pattern 123.

Referring to FIG. 11E, a semiconductor body 101 may be formed through a polishing process on the preliminary semiconductor body 101P so as to expose an upper surface of the first preliminary insulating pattern 113P′ and an upper surface of the third preliminary insulating pattern 124P′ of FIG. 11D. The first partial pattern 211 of FIG. 11D may be removed through the polishing process for the preliminary semiconductor body 101P, and a first insulating pattern 113′ may be formed through a polishing process for the first preliminary insulating pattern 113P′ so as to expose the upper surface of the first preliminary insulating pattern 113P′. Through the polishing process for the above-mentioned preliminary semiconductor body 101P, the second partial pattern 223 of FIG. 11D may be removed, and a third insulating pattern 124′ may be formed through a polishing process for a third preliminary insulating pattern 124P′ so as to expose an upper surface of the third preliminary insulating pattern 124P′.

The first insulating pattern 113′ may include a first portion 113a′ having a side surface in contact with the semiconductor body 101 and a second portion 113b′ extending from the first portion 113a and having a side surface in contact with the second insulating pattern 111. A lower surface of the first portion 113a′ of the first insulating pattern 113′ may include a region in contact with the semiconductor body 101 and a region from which the second portion 113b′ protrudes. The third insulating pattern 124′ may include a third portion 124a′ having a side surface in contact with the semiconductor body 101 and a fourth portion 124b′ extending from the third portion 124a and having a side surface in contact with the fourth insulating pattern 123. A lower surface of the third portion 124a′ of the third insulating pattern 124′ may include a region in contact with the semiconductor body 101 and a region from which the fourth portion 124b′ protrudes.

After the polishing process for the preliminary semiconductor body 101P, a process of forming a rear insulating layer 31 of FIG. 3A and bonding the rear insulating layer 31 to the first structure ST1 may be performed.

While example embodiments have been illustrated and described above, it will be apparent to those skilled in the art that modifications and variations could be made without departing from the scope of the present disclosure as defined by the appended claims.

What is claimed is:

1. A semiconductor device, comprising:
a first structure having a memory region; and
a second structure vertically overlapping the first structure and having a peripheral circuit region,
wherein the first structure includes:
a plurality of memory cells disposed within the memory region, each memory cell of the plurality of memory cells including a vertical channel transistor and an information storage structure; and
a cell routing interconnection line electrically connected to the plurality of memory cells, and
wherein the second structure includes:
a semiconductor body;
a rear insulating layer below the semiconductor body;
a device isolating pattern defining a peripheral active region of the semiconductor body and having a lower surface at a higher vertical level than a vertical level of a lower surface of the semiconductor body;
a first through-insulating pattern penetrating through the semiconductor body, the first through-insulating pattern including
a first insulating pattern including a first portion and a second portion over the first portion; and
a second insulating pattern between the second portion of the first insulating pattern and the semiconductor body, over the first portion of the first insulating pattern;
a second through-insulating pattern penetrating through the device isolating pattern and the semiconductor body below the device isolating pattern;
a peripheral transistor including a first peripheral source/drain and a second peripheral source/drain disposed within the peripheral active region, a peripheral channel region between the first peripheral source/drain and the second peripheral source/drain, and a peripheral gate disposed on the peripheral channel region; and
a through-via penetrating through the first through-insulating pattern and electrically connected to the cell routing interconnection line.

2. The semiconductor device of claim 1,
wherein a lower surface of the semiconductor body, a lower surface of the first through-insulating pattern, and a lower surface of the second through-insulating pattern are coplanar with each other.

3. The semiconductor device of claim 1,
wherein an upper surface of the first through-insulating pattern, an upper surface of the second through-insulating pattern, and an upper surface of the semiconductor body are coplanar with each other.

4. The semiconductor device of claim 1,
wherein the first portion is adjacent to the rear insulating layer and the second portion extends upward from the first portion; and
such that the first portion of the first insulating pattern separates the second insulating pattern from the rear insulating layer.

5. The semiconductor device of claim 4,
wherein the first insulating pattern includes a first insulating material, and
the second insulating pattern includes a second insulating material different from the first insulating material.

6. The semiconductor device of claim 4,
wherein an upper surface of the first portion of the first insulating pattern includes a first region from which the second portion of the first insulating pattern extends and a second region excluding the first region, and
the second region of the upper surface of the first portion is in contact with the semiconductor body.

7. The semiconductor device of claim 1,
wherein a lower surface of the first through-insulating pattern has a first width in a first direction, and
a lower surface of the second through-insulating pattern has a second width that is smaller than the first width in the first direction.

8. The semiconductor device of claim 1,
wherein the second through-insulating pattern includes:
a third insulating pattern including a third portion adjacent to the rear insulating layer and a fourth portion over and extending from the third portion; and
a fourth insulating pattern between the fourth portion of the third insulating pattern and the semiconductor body, over the third portion of the third insulating pattern.

9. The semiconductor device of claim 8,
wherein an upper surface of the third portion of the third insulating pattern includes a third region from which the fourth portion of the third insulating pattern extends, and a fourth region excluding the third region, and
the fourth region of the upper surface of the third portion is in contact with the semiconductor body.

10. The semiconductor device of claim 8,
wherein a lower surface of the fourth insulating pattern of the second through-insulating pattern is at a lower vertical level than a lower surface of the device isolating pattern.

11. The semiconductor device of claim 1,
wherein the device isolating pattern includes a first device isolating insulating film, a second device isolating insulating film in contact with a side surface and a lower surface of the first device isolating insulating film, and a third device isolating insulating film in contact with a side surface and a lower surface of the second device isolating insulating film,
the first device isolating insulating film and the third device isolating insulating film include a third insulating material, and
the second device isolating insulating film includes a fourth insulating material different from the third insulating material.

12. The semiconductor device of claim 11,
wherein the first through-insulating pattern includes a first through-insulating film, a second through-insulating film in contact with a side surface and a lower surface of the first through-insulating film, and a third through-insulating film in contact with a side surface and a lower surface of the second through-insulating film,
the first through-insulating film and the third through-insulating film include the third insulating material, and
the second through-insulating film includes the fourth insulating material.

13. A semiconductor device, comprising:
a first structure having a memory region; and
a second structure vertically overlapping the first structure and having a peripheral circuit region,
wherein the first structure includes:
a plurality of memory cells disposed within the memory region; and
a cell routing interconnection line electrically connected to the plurality of memory cells, and
wherein the second structure includes:
a semiconductor body;
a rear insulating layer disposed on a lower surface of the semiconductor body;
a first peripheral transistor including a first peripheral source/drain and a second peripheral source/drain disposed within a first peripheral active region of the semiconductor body, a first peripheral channel region between the first peripheral source/drain and the second peripheral source/drain, and a first peripheral gate disposed on the first peripheral channel region;
a first through-insulating pattern penetrating through the semiconductor body;
a device isolating pattern having a lower surface at a vertical level higher than a lower surface of the semiconductor body within the semiconductor body and spaced apart from the first through-insulating pattern in a horizontal direction; and
a through-via penetrating through the first through-insulating pattern and the rear insulating layer and electrically connected to the cell routing interconnection line,
wherein the first through-insulating pattern includes a first insulating pattern including a first portion adjacent to the rear insulating layer and a second portion disposed on the first portion, and a second insulating pattern disposed between a side surface of the second portion of the first insulating pattern and the semiconductor body.

14. The semiconductor device of claim 13,
wherein a side surface of the first portion of the first insulating pattern is in contact with the semiconductor body.

15. The semiconductor device of claim 13,
wherein the first insulating pattern includes silicon oxide, and
the second insulating pattern includes silicon nitride.

16. The semiconductor device of claim 13,
wherein the device isolating pattern includes a first device isolating insulating film, a second device isolating insulating film in contact with a side surface and a lower surface of the first device isolating insulating film, and a third device isolating insulating film in contact with a side surface and a lower surface of the second device isolating insulating film,
the first insulating pattern of the first through-insulating pattern, the first device isolating insulating film, and the third device isolating insulating film include a first insulating material, and
the second insulating pattern of the first through-insulating pattern and the second device isolating insulating film include a second insulating material different from the first insulating material.

17. The semiconductor device of claim 13,
wherein the second structure further includes:
a second peripheral transistor including a third peripheral source/drain and a fourth peripheral source/drain disposed within of a second peripheral active region of the semiconductor body, a second peripheral channel region between the third peripheral source/drain and the fourth peripheral source/drain, and a second peripheral gate disposed on the second peripheral channel region of the second peripheral active region, and
the device isolating pattern is disposed between the first peripheral transistor and the second peripheral transistor.

18. The semiconductor device of claim 13,
wherein the second structure further includes a second through-insulating pattern penetrating through the device isolating pattern and penetrating through the semiconductor body below the device isolating pattern, and
the second through-insulating pattern includes:
a third insulating pattern including a third portion over and adjacent to the rear insulating layer and a fourth portion extending from the third portion; and
a fourth insulating pattern between the fourth portion of the third insulating pattern and the semiconductor body, over the third portion of the third insulating pattern.

19. A semiconductor device, comprising:
a first structure having a plurality of memory cells disposed in a memory region and a cell routing interconnection line electrically connected to the plurality of memory cells; and
a second structure vertically overlapping the first structure and having a peripheral circuit region,
wherein the second structure includes:
a semiconductor body;
a device isolating pattern defining a peripheral active region of the semiconductor body;
a first through-insulating pattern penetrating through the semiconductor body;
a peripheral transistor including a first peripheral source/drain and a second peripheral source/drain disposed within the peripheral active region, a peripheral channel region between the first peripheral source/drain and the second peripheral source/drain, and a peripheral gate disposed on the peripheral channel region; and
a through-via penetrating through the first through-insulating pattern and electrically connected to the cell routing interconnection line, and
the first through-insulating pattern includes a first insulating pattern having a first portion having a lower surface coplanar with a lower surface of the semiconductor body and a second portion disposed on the first portion, and a second insulating pattern on a side surface of the second portion of the first insulating pattern.

20. The semiconductor device of claim 19,
wherein a first height of the first portion of the first insulating pattern in a vertical direction is smaller than a second height of the second portion of the first insulating pattern in the vertical direction.
